(19) United States
(12) Patent Application Publication
(10) Pub. No.: US 2019/0061970 A1
(43) Pub. Date: Feb. 28, 2019

(54) MULTI-ROTOR AERIAL DRONE WITH THERMAL ENERGY HARVESTING

(71) Applicant: QUALCOMM Incorporated, San Diego, CA (US)

(72) Inventors: Peng WANG, San Diego, CA (US); Jorge Luis ROSALES, San Diego, CA (US); Victor Adrian CHIRIAC, San Diego, CA (US)

(21) Appl. No.: 15/689,994

(22) Filed: Aug. 29, 2017

(51) Int. Cl. B64D 41/00; B64D 27/24; B64C 39/02; H02N 11/00; H01L 35/00

(52) U.S. Cl. CPC B64D 41/00; B64D 27/24; B64C 39/024; H02N 11/002; B64C 2201/165; B64C 2201/042; B64C 2201/066; B64C 2201/108; B64C 2201/127; H01L 35/00

(57) ABSTRACT

Some features pertain to a quad-rotor or other aerial drone having a thermoelectric generator (TEG) for harvesting waste heat from a processor of the drone. The TEG is positioned, in some examples, with its inner metal electrode coating adjacent the drone processor to function as the “hot” side of the TEG. The outer metal electrode coating of the TEG forms a portion of the outer surface of the housing of the drone to function as the “cold” side of the TEG. The inner and outer metal coatings of the TEG are coupled to a battery recharger so current generated by the TEG during operation of the drone can help recharge the drone battery to extend flight time. In some examples, an outer perimeter of the TEG extends into an airflow region near the drone rotors so propeller wash serves to cool the perimeter of the TEG.

### BACKGROUND

### Field

Various features relate to multi-rotor aerial drones or other Unmanned Aerial Vehicles (UAVs) and to energy harvesting methods and apparatus for use therein.

### Background

Multi-rotor aerial drones, e.g. quadrotors, or other UAVs have limited flight times due to limited on-board power resources. Total flight time can be affected by many factors such as the power consumed by the rotors and by any on-board equipment (e.g. control processor(s), telecommunication devices, video devices, industrial sensors, etc.). Due to practical limitations in battery capacity, the flight time of currently-available consumer drones and small UAV systems often varies from only five to thirty minutes. It would be advantageous to extend the flight time as much as possible.

### SUMMARY

Various features relate to an aerial drone having an energy harvesting device.

In one example, an aerial drone is disclosed. The aerial drone includes: a processor configured to control the aerial drone; a power supply configured to power the processor; and an energy harvesting device configured to convert heat generated by the processor into electricity for return to the power supply.

In another example, an apparatus for use with an aerial drone is disclosed. The apparatus includes: means for controlling the aerial drone; means for providing power to the means for controlling; and means for converting heat generated by the means for controlling into electricity for return to the power supply means.

In yet another example, a method for energy harvesting within an aerial drone having an energy harvesting device, a processor and a power supply is disclosed. The method includes: operating the processor of the aerial drone using electricity provided by the power supply; converting heat generated by the processor of the aerial drone into electricity using the energy harvesting device; and returning the electricity obtained by the energy harvesting device to the power supply.

In another example, a device for use with an aerial drone is disclosed. The device includes: first and second electrodes; a thermoelectric material composed of either only an N-type thermoelectric element or only a P-type thermoelectric element, with the thermoelectric material positioned between the first and second metal electrodes and with the thermoelectric material configured to generate a voltage in response to a temperature difference between the first and second metal electrodes; a power supply; and a circuit interconnecting the power supply and the first and second electrodes with the circuit configured to apply the voltage to the power supply to charge the power supply.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 is a schematic diagram illustrating components of an exemplary symmetric thermoelectric generator (TEG) within an aerial drone or unmanned aerial vehicle (UAV).

FIG. 2 is a top view of an exemplary aerial drone with a TEG.

FIG. 3 is a schematic side view of an exemplary aerial drone with a TEG, wherein the TEG forms a top surface of the main housing of the aerial drone.

FIG. 4 is another schematic side view of an exemplary aerial drone with a TEG, wherein the TEG is combined with a heat spreader that forms the top surface of the drone.

FIG. 5 is a schematic side view of an exemplary aerial drone with a TEG, wherein the TEG forms the entire perimeter of the main housing of the drone.

FIG. 6 is another schematic side view of an exemplary aerial drone with a TEG, wherein a TEG/heat spreader forms the entire perimeter of the main housing of the drone.

FIG. 7 is a schematic side view of an exemplary aerial drone with a TEG, wherein the TEG forms the top half of the main housing of the drone.

FIG. 8 is another schematic side view of an exemplary aerial drone with a TEG, wherein a TEG/heat spreader forms the top half of the main housing of the drone.

FIG. 9 summarizes an assembly procedure for assembling a processor package having a TEG attached to the process package using a thermal interface material (TIM).

FIG. 10 is a block diagram broadly illustrating features of an exemplary aerial drone or UAV with a TEG.

FIG. 11 is a flow diagram summarizing the assembly and use of the TEG processor package for use with an aerial drone or UAV.

FIG. 12 is a flow diagram illustrating further aspects of the assembly and use of the TEG processor package for use with an exemplary aerial drone or UAV.

FIG. 13 is a block diagram illustrating various components of an exemplary aerial drone or UAV.

FIG. 14 illustrates various electronic devices that may be used in communication with any of the aforementioned exemplary aerial drones or UAVs.

FIG. 15 is a schematic diagram illustrating components of an exemplary asymmetric N-type TEG within an aerial drone or other UAV.

FIG. 16 is a schematic diagram illustrating components of an exemplary asymmetric P-type TEG within an aerial drone or other UAV.

FIG. 17 is a perspective view of an exemplary aerial drone computer model used to assess temperature TEG profiles for various processor chip power configurations.

FIG. 18 is a top view of the exemplary aerial drone model of FIG. 17 with a single chip.

FIG. 19 is a top view of the exemplary aerial drone model of FIG. 17 showing temperature profiles of the top or outer metal surface (i.e. T_{cold}) of the TEG of the drone.

FIG. 20 is a top view of the exemplary aerial drone model of FIG. 17 showing temperature profiles of the bottom or inner metal surface (i.e. Tₕₒₜ) of the TEG of the drone.

FIG. 21 is a top view of the exemplary aerial drone model of FIG. 17 with two chips.

FIG. 22 is a top view of the exemplary aerial drone model of FIG. 17 showing temperature profiles of the top or outer metal surface (i.e. T_{cold}) of the TEG of the drone.

FIG. 23 is a top view of the exemplary aerial drone model of FIG. 17 showing temperature profiles of the bottom or inner metal surface (i.e. Tₕₒₜ) of the TEG of the drone.

### DETAILED DESCRIPTION

In the following description, specific details are given to provide a thorough understanding of the various aspects of the disclosure. However, it should be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some features pertain to an aerial drone having a solid state energy harvesting system or apparatus. In some implementations, the aerial drone has one or more rotors, a processor for controlling the rotor(s), and a power supply. The energy harvesting system is configured to convert heat generated within the aerial drone into electrical energy to thereby harvest or capture heat that might otherwise be lost and to then convert the heat to electrical energy for return to the power supply.

Briefly, in some implementations, the energy harvesting system includes a thermoelectric generator (TEG) or other suitable solid state device or component that converts heat to electrical energy. A TEG is a solid state device for converting heat directly into electrical energy through the Seebeck effect by, e.g., using internal thermocouple elements such as P-type and N-type elements. By harvesting energy that would otherwise be lost as heat, overall flight time of an aerial drone can be extended, often by 5 or 10% or more, as compared to comparable flight times without energy harvesting.

In some examples, the TEG forms all or part of the enclosure or housing of the drone to help protect electronic components of the drone from dust, moisture, etc. That is, a “hybrid enclosure” is provided that serves the dual purposes of energy harvesting and device protection. In some examples, a portion of the inner surface of the TEG is coupled (or mounted) to the main processor of the drone to directly receive heat energy from the processor. An outer surface of the TEG covers all or part of the main enclosure of the drone, especially top portions exposed to airflow from the rotors. The TEG converts heat from the processor to electrical energy for return to an on-board battery (or other power cell). By positioning or disposing the outer surface of the TEG in the airflow region of the drone, the TEG can benefit from a greater thermal gradient (ΔT) than if the TEG were positioned entirely within the drone housing. In this regard, the greater the ΔT between the opposing “hot” and “cold” surfaces of the TEG, the greater the amount of electrical energy that can be harvested via the thermoelectric Seebeck Effect. More specifically, the efficiency of power generation obtained from the Seebeck Effect using a TEG is determined by the ratio of the power thermoelectrically generated by the TEG to the input heat. The maximum efficiency can be represented with the following equation:

$${η}_{max} = \frac{Δ T}{{T}_{h}} \frac{\sqrt{1 + Z \cdot {T}_{avg}} - 1}{\sqrt{1 + Z \cdot {T}_{avg}} + \frac{{T}_{c}}{{T}_{h}}} \qquad ( 1 )$$

where ηₘₐₓ is the maximum efficiency, ΔT is the temperature difference between opposing sides of the TEG, Tₕ is the temperature of the “hot” side, T_{c} is the temperature of the “cold” side, T_{avg} is the average temperature of the device (i.e. (Tₕ−T_{c})/2), and Z is a coefficient that may be derived from the electrical resistivity and thermal conductivity of the various thermocouple devices within the TEG and their Seebeck coefficients. As is apparent from Equation (1), a larger temperature difference between the “cold surface” and the “hot surface” leads to a higher thermal-to-electricity conversion efficiency. In addition, the conversion efficiency increases significantly as the dimensionless thermoelectric figure of merit value (i.e. ZT) increases.

In some examples, particularly where a portion of the TEG is positioned on the outside of the drone, the TEG has a bi-layer structure with aluminum (or other heat-spreading components or materials) coupled to an outer surface of the TEG. The aluminum layer protects the TEG and helps spread heat laterally to provide increased ΔT and thus an increase in the amount of harvested energy. In some examples, the TEG is a commercial “off the shelf” symmetric device that exploits a traditional N/P configuration of alternating P-type and N-type (doped) elements separated by air gaps. In other examples, the TEG has an asymmetric design with only an N-type or a P-type element, which can be easier to fabricate than an N/P device since the asymmetric design is a simpler device.

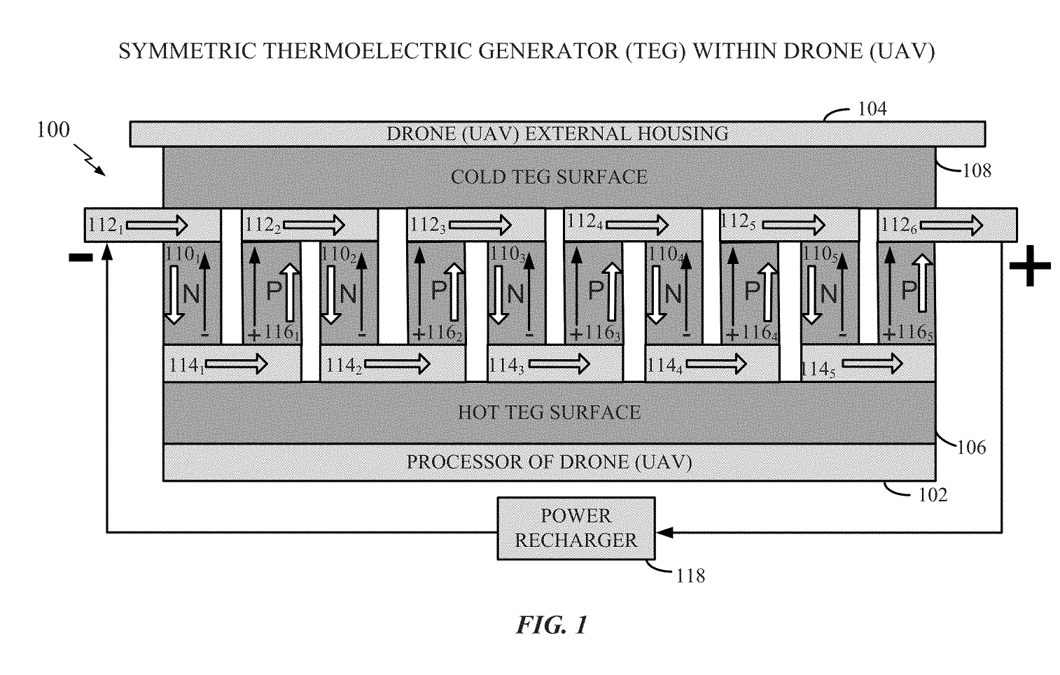

FIG. 1 illustrates an example of a symmetric design where a TEG 100 is coupled between a processor 102 of the drone and an external housing 104 of the drone. The processor 102 is coupled to a first (inner) surface 106 of the TEG, referred to herein as the “hot” surface. In some examples, the hot surface 106 of the TEG may be coupled to the processor 102 using a thermal paste, not shown, or another thermal interface material (TIM). The opposing second (outer) surface 108 of the TEG, referred to herein as the “cold” surface, is coupled to an inner surface of the housing 104 (or the surface 108 may instead form all or part of the external housing). In the example of FIG. 1, the TEG 100 includes five pairs of P/N thermocouple elements, although more or fewer may be used and, in some TEGs, hundreds or thousands or more may be employed. A first N-type element 110₁ is coupled between a first cold-side electrode 112₁ and a first hot-side electrode 114₁. A first P-type element 116₁ is coupled between the first hot-side electrode 114₁ and a second cold-side electrode 112₂. The first N-type element 110₁ and the corresponding first P-type element 116₁ form a first pair of P/N elements, which are separated from one another by a vacuum (or air) gap.

In use, heat from the hot side of the TEG 100 warms the negative end of the N-type element 110₁ and the positive end of P-type element 116₁, relative to their opposing colder ends, thus generating a ΔT and inducing a voltage between their opposing ends that causes current to flow in the direction of the arrows of the figure, i.e. current flows from cold-side electrode 112₁ through hot-side electrode 114₁ and then into cold-side electrode 112₂. Additional pairs of P/N elements (pairs 110₂/116₂-110₅/116₅), which are connected via additional pairs of electrodes (electrodes 112₂/114₂-112₅/114₅), likewise cause current to flow through corresponding electrodes, as shown, feeding into a final cold-side electrode 112₆. The first cold-side electrode 112₁ is used as a negative terminal and the last cold-side electrode 112₆ is used as a positive terminal, with the resulting current fed through a power recharger 118 for recharging batteries (not separately shown in FIG. 1) of the drone. The TEG can be quite thin, e.g., 500 microns.

The alternative asymmetric TEG design is described in detail below.

Exemplary Aerial Drone with TEG

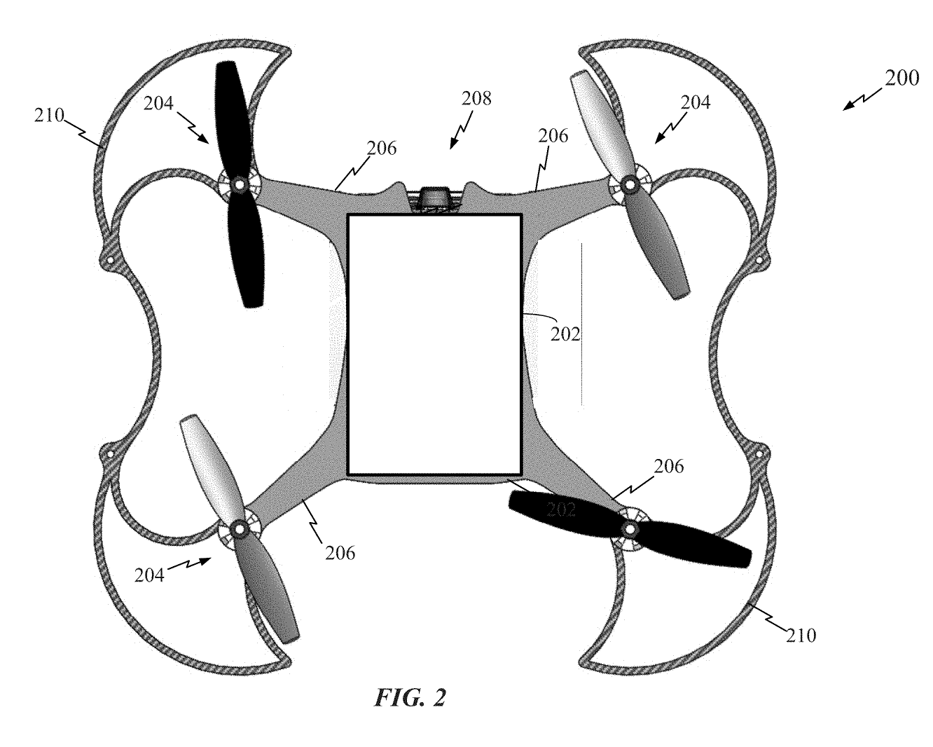

FIG. 2 provides a top view of an illustrative aerial drone 200 with a TEG 202 (either symmetric or asymmetric) that forms part of the top or upper part of a central housing of the drone. The aerial drone 200 is a so-called “quad-rotor” with four rotor systems or propeller systems 204 configured to provide aerodynamic lift. In other examples, more or fewer rotors are provided. In the example of FIG. 2, each rotor system 204 is installed at the end of a supporting strut (or “arm”) 206 and is controlled by a central control processor (not shown in FIG. 2) via connection lines or wires (also not shown) within the struts 206. The processor is operative to control all or some of the functions and features of the aerial drone and is contained within a central control module or housing 208 of the drone.

In the example of FIG. 2, the drone includes blade guards or bumpers 210 to protect individuals from injury or objects from damage in the event of a collision. The blade guards 210 also protect the blades of the rotor systems 204 from damage. In some examples, the aerial drone may be of a conventional design, other than the TEG 202, a corresponding power recharger and any modifications provided to accommodate and/or mount, position or couple the TEG. As such, most of the features of the drone itself will not be described in detail herein. Rather, the descriptions will be directed primarily to the configuration and operation of the TEG 202 and the coupling/mounting/installation of the TEG in or on the drone to facilitate energy harvesting from heat generated by the drone, especially the processor of the drone.

As shown in FIG. 2, the TEG 202 may include portions (such as corner portions) that are positioned in proximity to the rotors 204 in an airflow region of the drone, i.e. a region where air flows past the drone while in operation. In the example of FIG. 2, the TEG 202 is rectangular and covers only a top or upper portion of the housing. However, other shapes may be used for the TEG, and larger or smaller portions of the drone may be enclosed in or formed by the TEG. In some examples, more of the TEG is positioned in the airflow regions of the drone. In use, heat from the processor (and other internal components of the drone) heats the inner surface of the TEG to generate a ΔT relative to the outer surface of the TEG to produce a voltage for recharging internal batteries of the drone (not shown in FIG. 2). By extending or protruding the TEG into airflow regions, portions of the outer surface of the TEG 202 are thereby cooled via convection by air flow (which will be generally cooler than air within the housing of the drone where the inner surface of the TEG is positioned), thereby increasing the ΔT of the TEG to increase TEG efficiency and permit a greater amount of heat to be harvested.

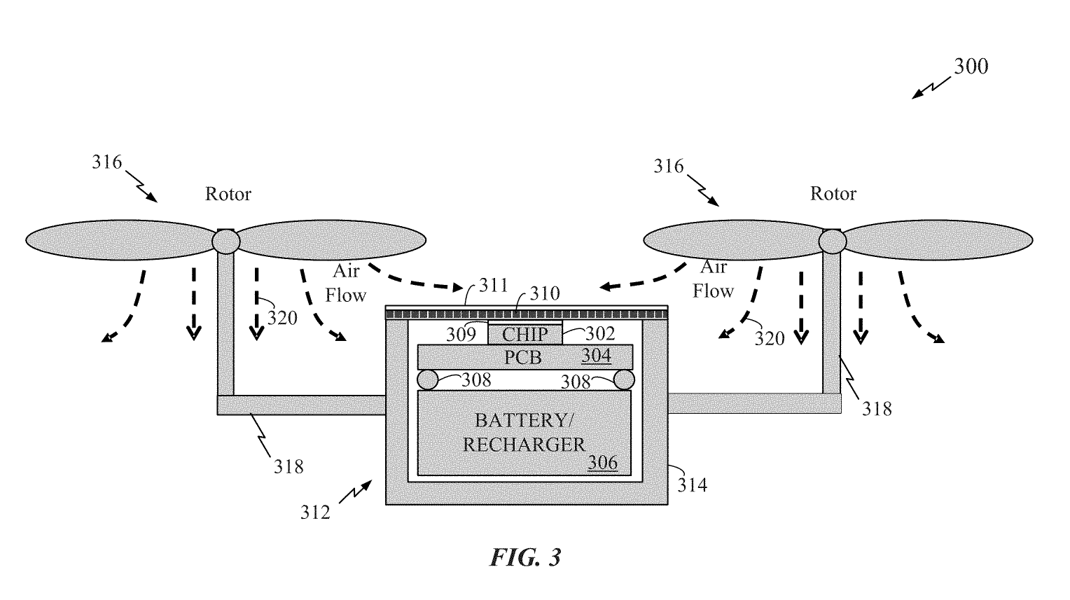

FIG. 3 provides a side schematic view of an exemplary drone design 300, where the processor is a chip 302 coupled to a printed circuit board (PCB) 304, positioned above a battery/recharger 306 and separated therefrom by spacers 308. A top or upper portion of processor chip 302 is coupled to (or affixed to, mounted to, or simply abuts) an inner metal coating 309 of a TEG 310 that provides the hot-side electrode for the TEG. An outer surface of TEG 310 includes another metal coating 311, which forms the cold-side electrode for the TEG. Note that, in this example, the inner metal coating 309 only extends the length of the TEG. The outer metal coating 311 extends the width of the top of the drone. The TEG 310 and its metal coatings form a top portion of a housing 312 that also includes side and bottom or lower portions 314. (A TIM, not shown in FIG. 3, may be used between the chip and the TEG in this and other design examples herein, or between any two components that are to be thermally coupled.) Electrical connection lines (not shown) connect the battery/recharger 306 with the inner metal coating 309 and the outer metal coating 311 for recharging the battery using electrical current provided by the TEG.

The drone 300 also includes rotors 316 mounted to (or coupled to) the housing 312 via struts 318. As shown by way of dashed arrows, a portion of the airflow 320 produced by the rotors 316 passes over the TEG 310, helping to cool the top or upper (“cold”) surface of the TEG relative to the inner (“hot”) surface, thus producing a larger ΔT than might otherwise be achieved if the top or upper surface of the TEG was not positioned in the airflow region, to thereby permit harvesting of a greater amount of energy. Note that only some of the components of the drone are shown in the figure, so as not to obscure the TEG and other notable features, such as the processor chip, the PCB and the battery/recharger.

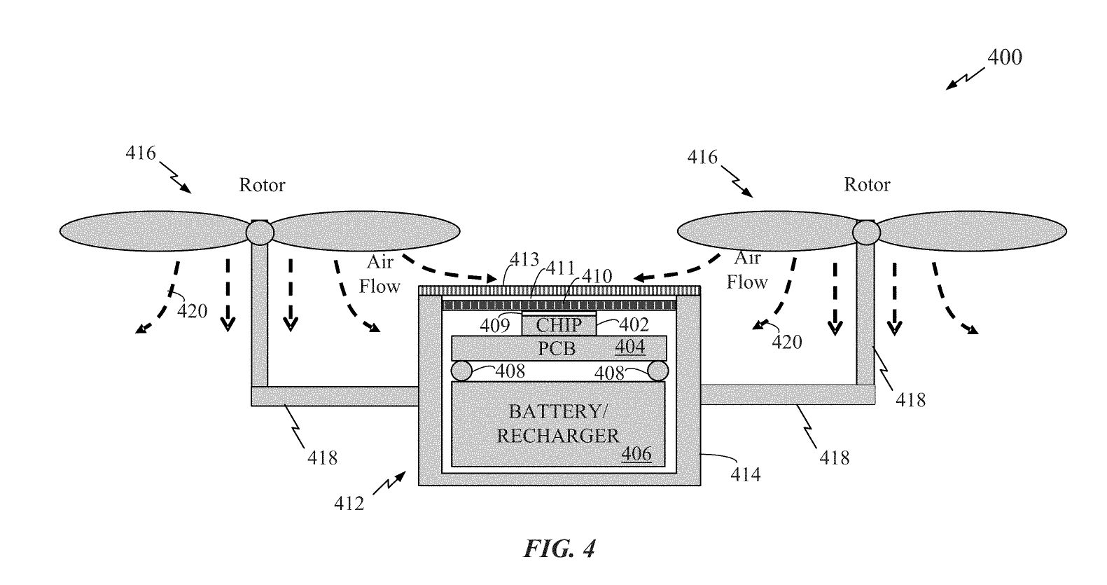

FIG. 4 provides a side schematic view of another exemplary drone design 400, where the processor is again a chip 402 coupled to a PCB 404 above a battery/recharger 406 and separated by spacers 408. The top or upper portion of processor chip 402 is again coupled to an inner metal coating 409 of a TEG 410, which also has an outer metal coating 411. Electrical connection lines (not shown) connect the battery/recharger 406 with the inner metal coating 409 and the outer metal coating 411 for recharging the battery using electrical current provided by the TEG. In this example, a heat spreader/protector material 413 forms a top or upper portion of the housing 412 (that also includes side and bottom or lower panels or portions 414). The heat spreader/protector 413 extends beyond the ends of the TEG 410 to spread or draw heat away from the TEG, thereby helping to cool the top surface of the TEG and produce a larger ΔT than might otherwise be achieved without the heat spreader. The heat spreader/protector 413 also serves to protect the TEG 410 and the outer metal coating 411 of the TEG from damage or weathering by rain, wind-blown sand, etc. As with the example of FIG. 3, the drone 400 includes rotors 416 mounted or coupled to the housing 412 via struts 418. A portion of the airflow 420 passes over the heat spreader/protector 413 and the TEG 410, further helping to cool the outer surface of the TEG relative to its inner surface. Again, only some components of the drone are shown in the figure to not obscure the TEG and other notable components. The heat spreader/protector 413 provides one example of a means for spreading heat.

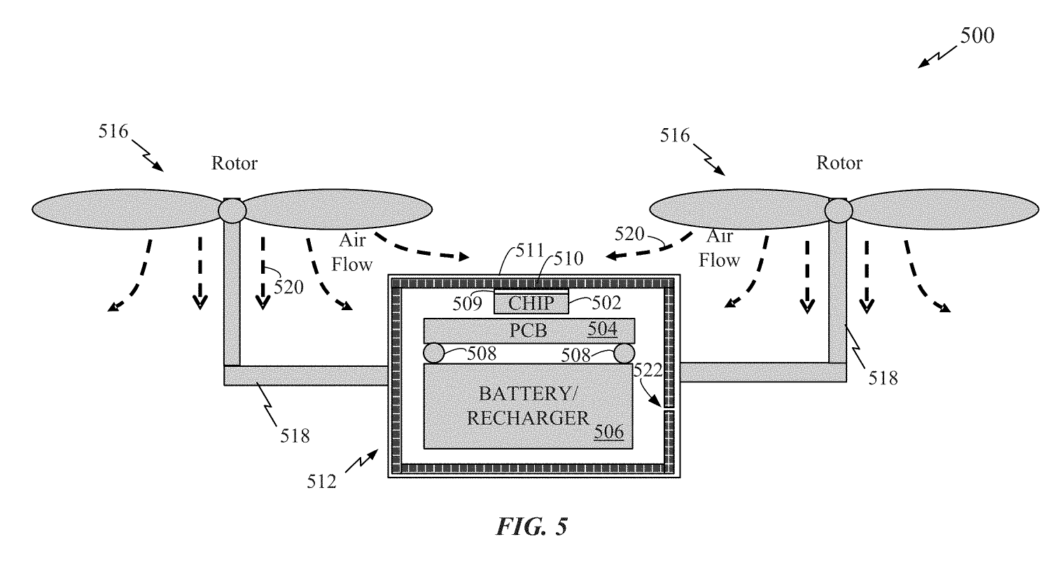

FIG. 5 provides a side schematic view of yet another exemplary drone design 500, where the processor is again a chip 502 coupled to a PCB 504 above a battery/recharger 506 and separated by spacers 508. The top or upper portion of processor chip 502 is again coupled to an inner metal coating 509 of a TEG 510 that also has an outer metal coating 511. In this example, however, the TEG forms the entire housing of the drone. With this design, the TEG exposes a large surface area to external air, which may thereby produce a larger ΔT than might otherwise be achieved. As with the examples above, electrical connection lines (not shown) connect the battery/recharger 506 with the inner metal coating 509 and the outer metal coating 511. The drone 500 also includes rotors 516 mounted or coupled to the housing 512 via struts 518. A portion of the airflow 520 produced by the rotors 516 again passes over portions of the TEG 510. Energy harvested by the TEG is used to help recharge the battery 506. Note that since the entire housing of the drone is formed of a TEG, an opening 522 is left through the inner surface of the TEG to permit an electrical connection (not shown) to be made between the outer metal electrode coating 511 and the internal battery/recharger 506 of the drone.

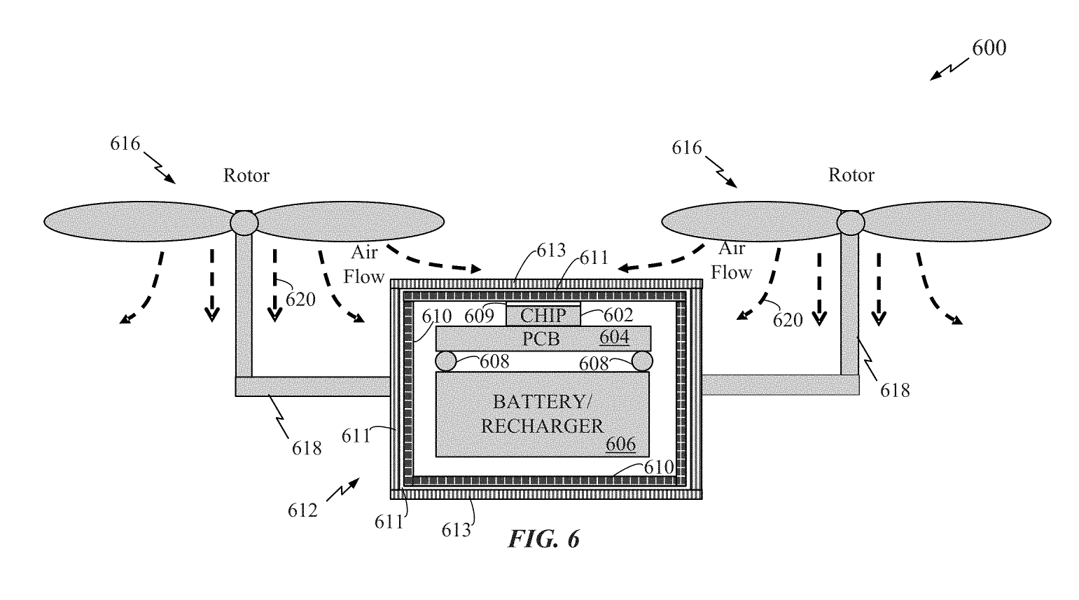

FIG. 6 provides a side schematic view of still another exemplary drone design 600, where the processor is again a chip 602 coupled to a PCB 604 above a battery/recharger 606 and separated by spacers 608. The top or upper portion of processor chip 602 is coupled to an inner metal coating 609 of a TEG 610, which also has a metal outer coating 611. In this example, the TEG 610 forms the entire inner surface of the housing of the drone, while a heat spreader/protector 613 forms the entire outer surface of the housing of the drone. As with the preceding design, the TEG is fairly large since the TEG extends around the entire housing. The heat spreader/protector 613 serves to spread or draw heat from warmer portions of the TEG (such as those adjacent to the chip 602) to other portions of the housing to more efficiently cool the outer surface of the TEG and thereby help increase ΔT, allowing for the harvesting of more heat. The heat spreader/protector 613 also serves to protect the outer metal coating 611 and the TEG 610 from damage or weathering. As with the examples above, electrical connection lines (not shown) connect the battery/recharger 606 with the inner metal coating 609 and the outer metal coating 611. An opening (not shown) may be provided through the TEG 610 to permit connection to the outer metal coating. The drone 600 includes rotors 616 mounted or coupled to the housing 612 via struts 618. A portion of the airflow 620 produced by the rotors 616 passes over portions of the heat spreader/protector 613 to help cool those portions via convection.

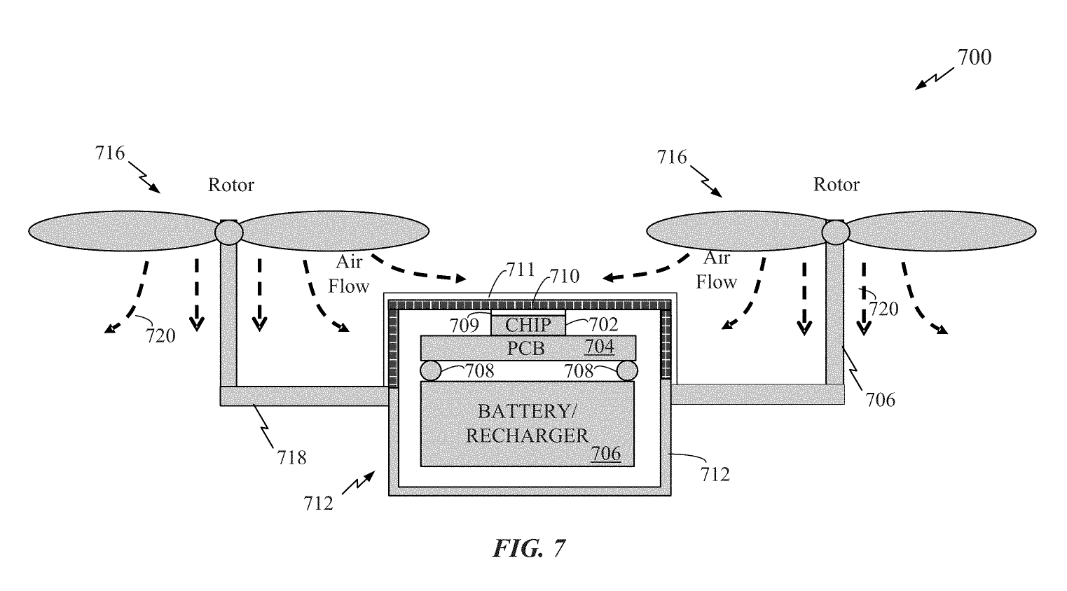

FIG. 7 provides a side schematic view of another exemplary drone design 700, where the processor is again a chip 702 coupled to a PCB 704 above a battery/recharger 706 and separated by spacers 708. The top or upper portion of processor chip 702 is coupled to an inner metal coating 709 of a TEG 710 that also has an outer metal coating 711. In this example, the TEG 710 forms the top half portion of the housing of the drone, while the bottom or lower half is otherwise conventional housing material 712. The TEG is still fairly large since the TEG forms the top or upper half of the drone housing. As with the examples above, electrical connection lines (not shown) connect the battery/recharger 706 with the inner metal coating 709 and the outer metal coating 711. The drone 700 includes rotors 716 mounted or coupled to the housing 712 via struts 718. A portion of the airflow 720 produced by the rotors 716 passes over portions of the TEG 710 to help cool those portions via convection.

FIG. 8 provides a side schematic view of still yet another exemplary drone design 800, where the processor is again a chip 802 coupled to a PCB 804 above a battery/recharger 806 and separated by spacers 808. The top or upper portion of processor chip 802 is coupled to an inner metal coating 809 of a TEG 810 that also has an outer metal coating 811. The outer coating 811 of the TEG 810 is enclosed in a heat spreader/protector 813 that both helps spread heat and protect the TEG from the elements. In this example, the TEG 810 and the heat spreader/protector 813 together form the top or upper half of the housing, while the bottom or lower half is an otherwise conventional housing material 812. As with the examples above, electrical connection lines (not shown) connect the battery/recharger 806 with the inner metal coating 809 and the outer metal coating 811. The drone 800 includes rotors 816 mounted or coupled to the housing 812 via struts 818. A portion of the airflow 820 produced by the rotors 816 passes over portions of the TEG 810 to help cool those portions.

### Exemplary Assembly Procedures

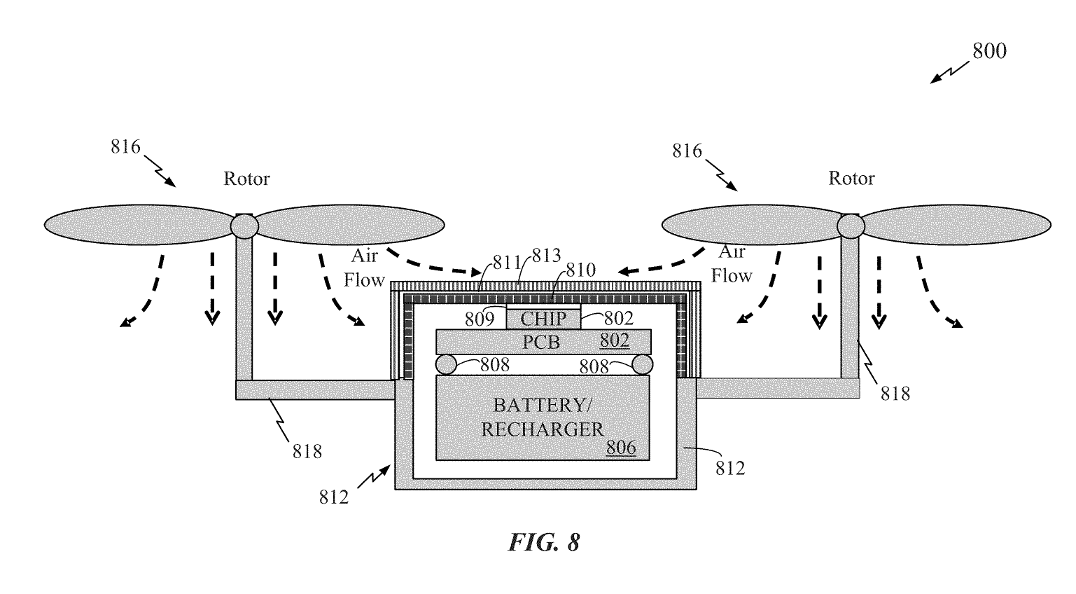

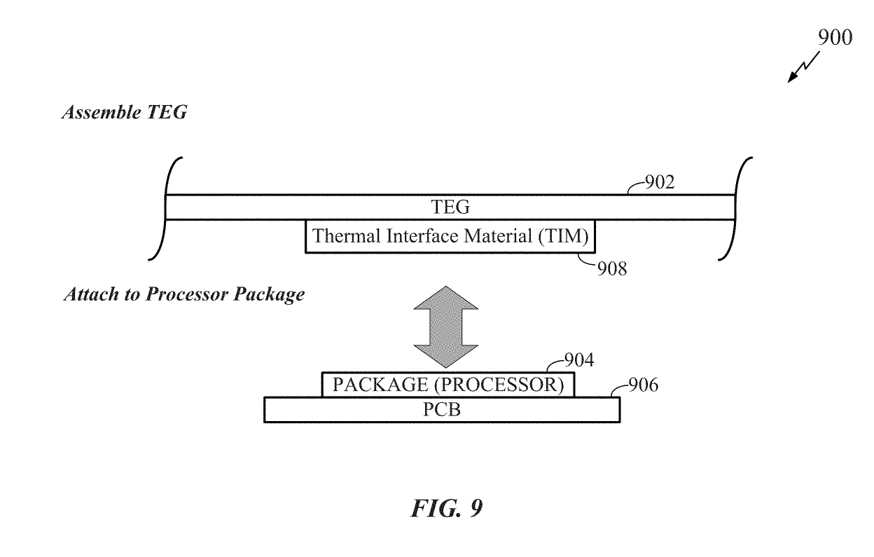

FIG. 9 summarizes a procedure 900 for assembling an apparatus having a TEG 902 and a processor 904 or other processing package (which may include a die package). Since the TEG 902 might be quite large compared to the processor, only a portion of the TEG 902 is shown in FIG. 9. Briefly, the processor 904 is coupled to a PCB 906. A TIM 908, such as a thermal paste, thermal pads, thermal greases or other TIM solutions, may be applied to the underside of the TEG 902. In one example, the thermal paste is a high-density polysynthetic silver thermal compound, such as compounds sold under the tradename Artic Silver™. The TEG 902 is then attached to a top or upper side or surface of the processor 904. That is, a first general fabrication procedure includes assembling the TEG 902 and the TIM 908. A second general fabrication procedure includes attaching the processor 904 to the TEG 902 via the TIM 908. Note that, in some examples, the TEG 902 is attached to the processor 904 after the processor/PCB has been installed in the housing of the drone. In other examples, the TEG 902 may be attached to the processor 904 before the resulting combined apparatus is installed in the housing. Note also that the TIM 908 represents just one example of a means for coupling the TEG to the processor. In other examples, the TEG may be attached to the processor using clamps, brackets, clasps or other suitable devices or may simply abut the processor.

### Exemplary Components and Procedures

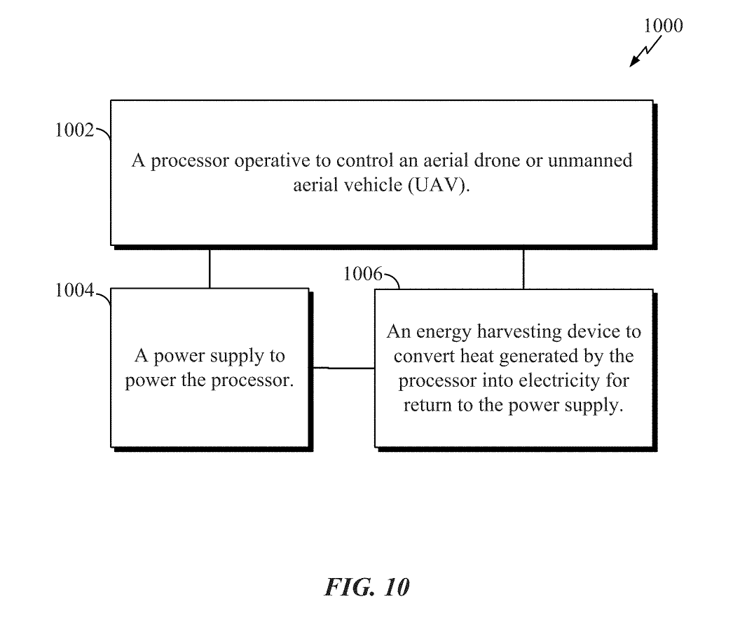

FIG. 10 is a block diagram 1000 broadly summarizing components of a UAV equipped for energy harvesting. A processor 1002 is operative to control the UAV. A power supply 1004 supplies power to the processor. An energy harvesting device 1006 is provided to convert heat generated by the processor into electricity for return to the power supply. The processor 1002 is one example of a means for controlling the UAV. The power supply 1004 is one example of a means for providing power to the processor means. The energy harvesting device 1006 is one example of a means for converting heat generated by the processor means into electricity for return to the power supply means.

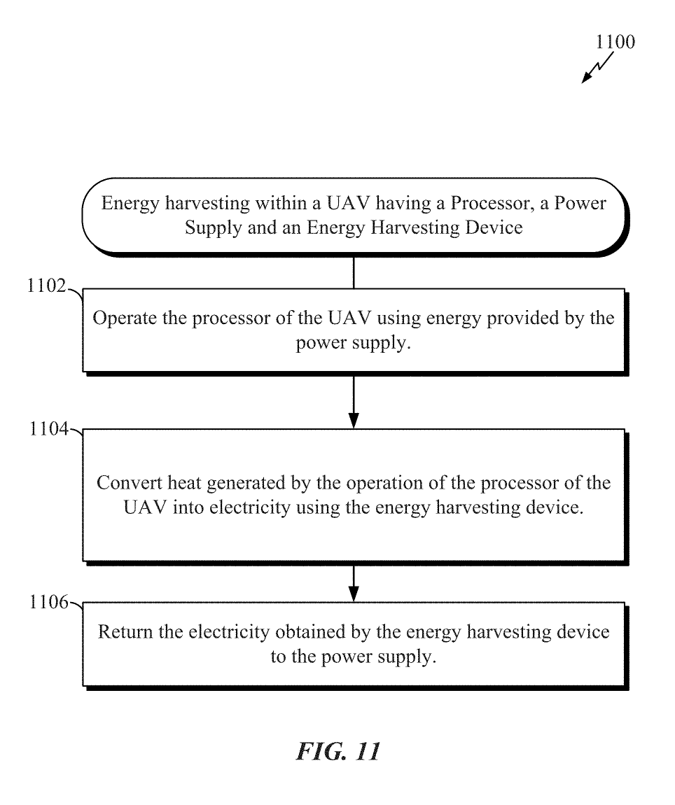

FIG. 11 is a flow diagram 1100 broadly summarizing aspects of the method or procedure for energy harvesting within a UAV (or other aerial drone) having an energy harvesting device, a processor, and a power supply. At 1102, the processor of the UAV is operated using electricity provided by the power supply. At 1104, the energy harvesting device, which may include a TEG, converts heat generated by the operation of the processor of the UAV into electricity. At 1106, a circuit returns the electricity obtained by the energy harvesting device to the power supply to, for example, further power the processor or other components of the UAV.

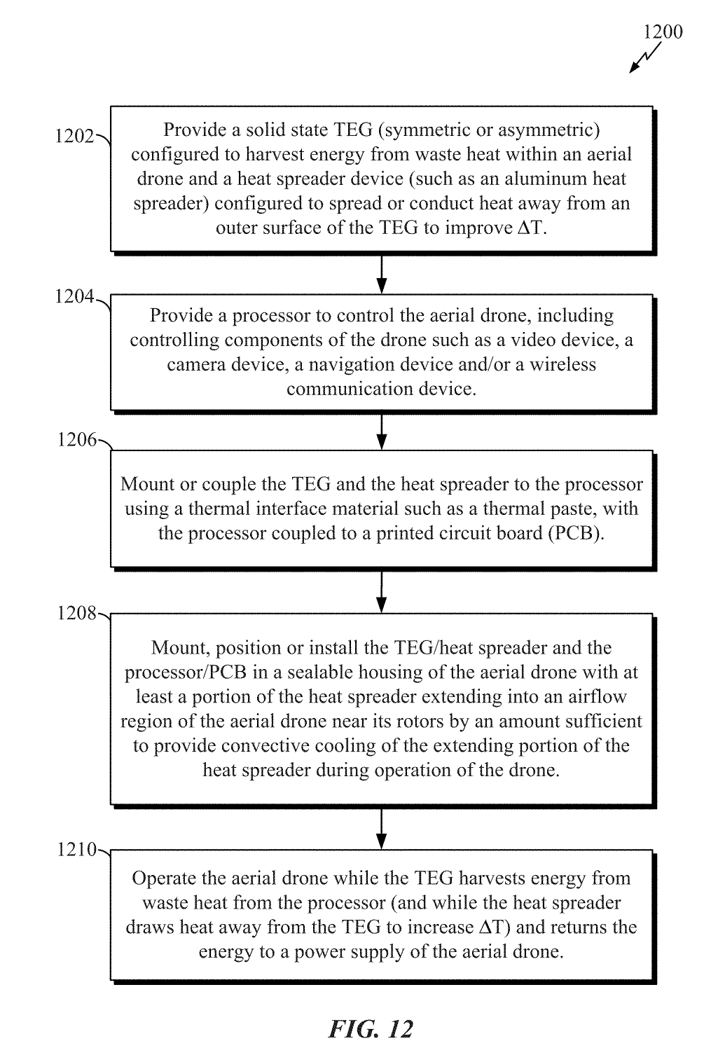

FIG. 12 is a flow diagram 1200 providing exemplary details of the method of FIG. 10. At 1202, a solid state TEG (either symmetric or asymmetric) is configured by product engineers to harvest energy from waste heat within an aerial drone. At 1202, a heat spreader device is also provided (such as an aluminum heat spreader) and configured by product engineers to spread or conduct heat away from an outer surface of the TEG to increase ΔT. At 1204, a processor is provided by product engineers to control the aerial drone, including controlling components of the drone such as a video device, a camera device, a navigation device and/or a wireless communication device. At 1206, the TEG and the heat spreader are coupled to the processor by manufacturing personnel using a TIM such as a thermal paste with the processor coupled to a PCB. At 1208, the TEG/heat spreader and the processor/PCB are installed by manufacturing personnel in a sealable central housing of the aerial drone with at least a portion of the heat spreader extending into an airflow region of the aerial drone near the rotors by an amount sufficient to provide convective cooling of the extending portion of the heat spreader during operation of the aerial drone. At 1210, the aerial drone is operated by an end user while the TEG harvests energy from waste heat from the processor (and while the heat spreader draws heat away from the TEG to increase ΔT). At 1210, the energy harvested is returned via a circuit to the power supply of the aerial drone to help recharge the power supply.

### Further Exemplary Aerial Drones and Components

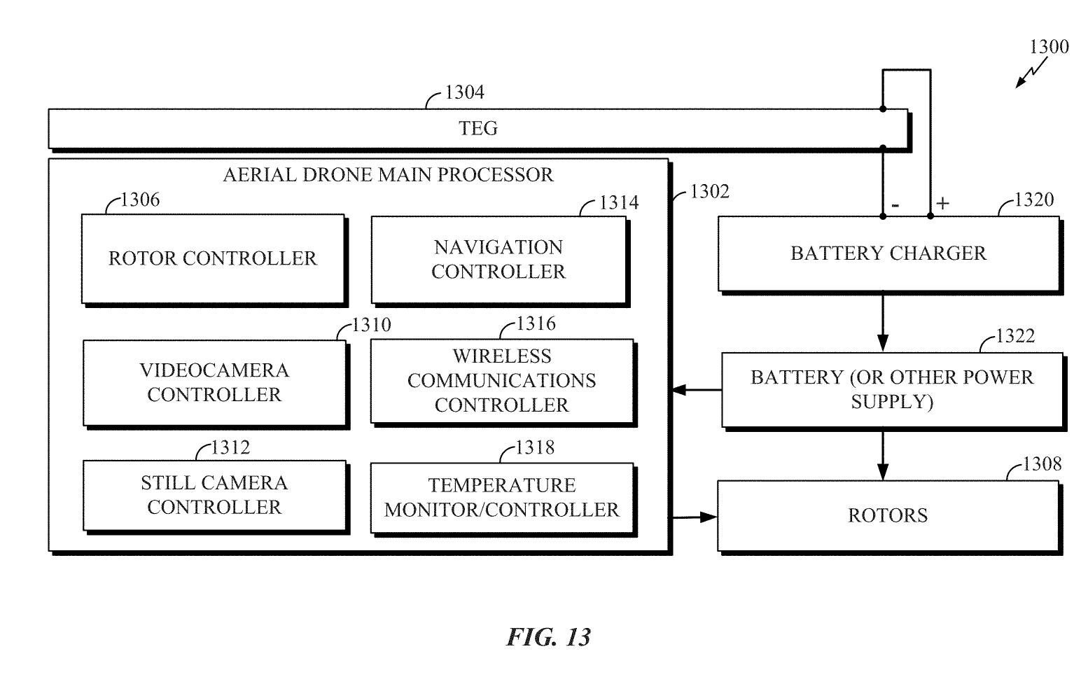

FIG. 13 is a block diagram illustrating various components of an aerial drone 1300. In this example, the drone includes an aerial drone main processor 1302 and a TEG 1304, which may be coupled/mounted/installed in or on the drone as already discussed. The processor 1302 includes a rotor controller 1306 for controlling one or more sets of rotors or propellers 1308. The processor 1302 in this example also includes: a videocamera controller 1310 for controlling a videocamera (not shown); a still camera controller 1312 for controlling a still camera (not shown) such as a digital camera equipped for single-image photography rather than video photography; a navigation controller 1314 for controlling a navigation device such as a global positioning system (GPS) device (not shown) equipped to track the location of the drone; a wireless communications controller 1316 for controlling a wireless communication device such as a cellular or radio communication device (not shown) equipped to receive commands from a user or operator; and a temperature monitor/controller 1318 for controlling a temperature monitor (not shown) to assess the temperature of the processor or other components of the aerial drone. A battery charger 1320 is coupled to the positive and negative (hot and cold) sides of the TEG 1304 to receive an electrical current for use in recharging a battery 1322 or other power supply. These are exemplary components and, in other drones, more or fewer components may be provided. Multiple processors may be employed in some examples.

Exemplary Electronic Devices for Use in Communication with the Drone

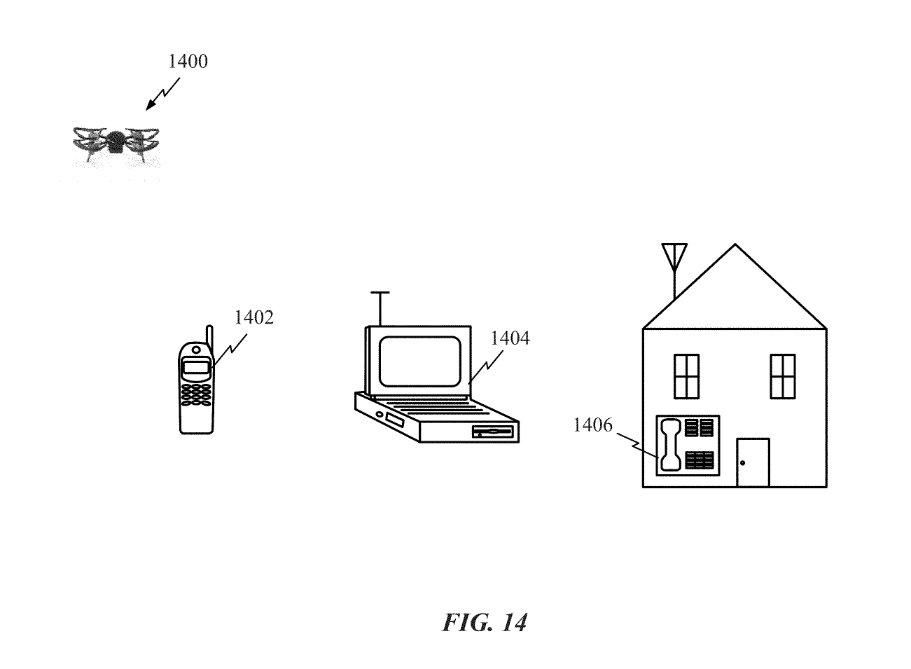

FIG. 14 illustrates various electronic devices that may be used in communication with any of the aforementioned aerial drones for controlling the drones and/or receiving signals therefrom. For example, a mobile telephone 1402, a laptop computer 1404 and a fixed location terminal 1406 may be equipped to control and/or receive signals from a drone 1400. The devices 1402, 1404, 1406 illustrated in FIG. 14 are merely exemplary. Other electronic devices that may also be used in communication with the aerial drone include, but are not limited to, drone remote controllers, mobile devices, hand-held personal communication systems (PCS) units, portable data units such as personal digital assistants, GPS enabled devices, navigation devices, set top boxes, video players, entertainment units, fixed location data units such as meter reading equipment, communications devices, smartphones, tablet computers, virtual reality (VR) headsets or any other device that stores or retrieves data or computer instructions, or any combinations thereof.

### Exemplary Asymmetric TEG for Use in Aerial Drone

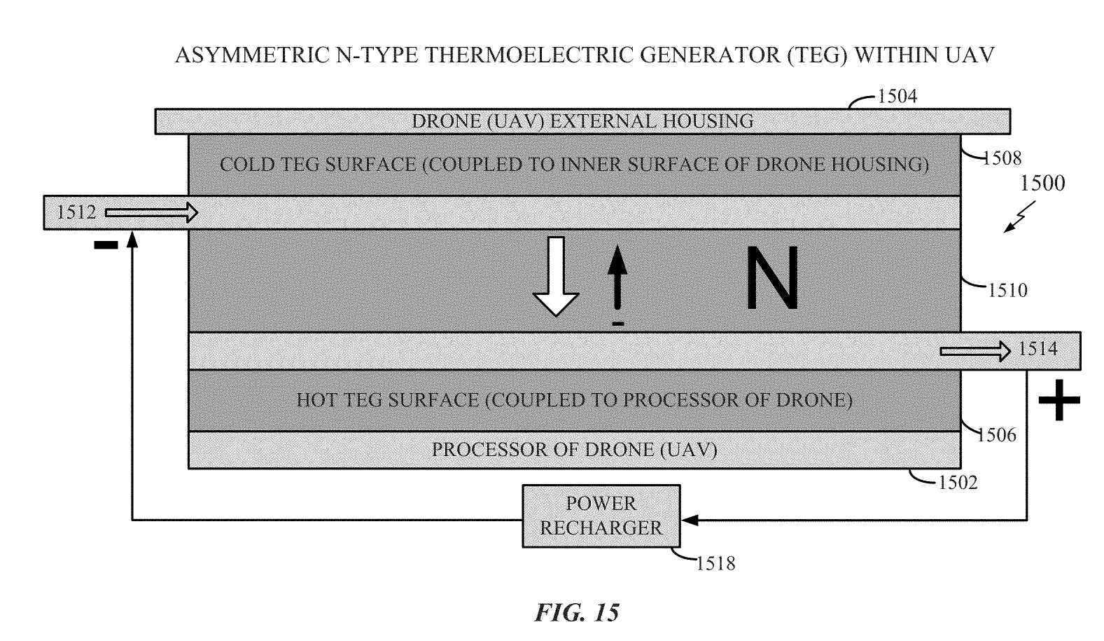

FIG. 15 illustrates an example of an N-type asymmetric TEG design where a TEG 1500 is coupled between a processor 1502 of the drone and an external housing 1504 of the drone. As with the symmetric design shown in FIG. 1, the processor 1502 is coupled to a first “hot” surface 1506 of the TEG. The opposing second “cold” surface 1508 of the TEG is coupled to an inner surface of the housing 1504. In the asymmetric design of FIG. 15, the TEG 1500 includes only a single large N-doped thermocouple element rather than alternating P and N elements. As shown in FIG. 15, the N-type element 1510 is coupled between a cold-side electrode 1512 and a hot-side electrode 1514. In use, heat from the hot side of the TEG 1500 warms the negative end of the N-type element 1510, relative to the opposing colder end, thus generating a ΔT and inducing a voltage between the opposing ends that causes current to flow in the direction of the arrows of the figure, i.e. current flows from cold-side electrode 1512 through N-type element 150 and then into hot-side electrode 1514, with the resulting current fed through a power recharger 1518 for recharging batteries (not shown in FIG. 15) of the drone. Since there is only an N-type element, less current will generally flow within a given area of the TEG than with a symmetric TEG as in FIG. 1. However, no alternating air gaps are needed and so the TEG of FIG. 15 should be less expensive to fabricate than the TEG of FIG. 1.

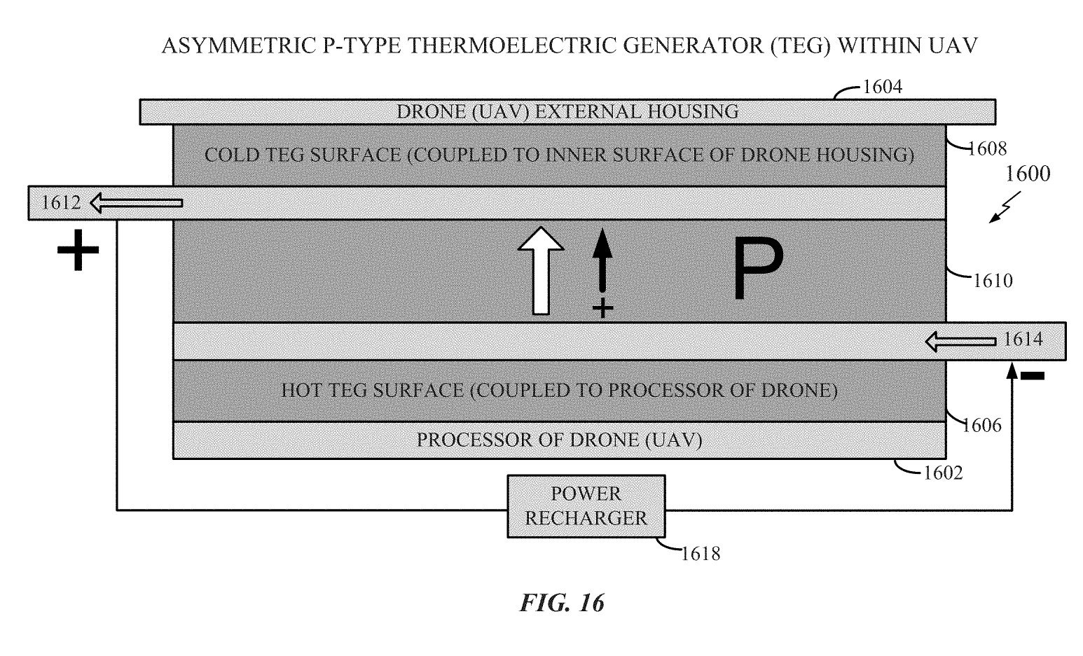

FIG. 16 illustrates an example of a P-type asymmetric TEG design where a TEG 1600 is coupled between a processor 1602 of the drone and an external housing 1604 of the drone. As with the design shown in FIG. 15, the processor 1602 is coupled to a first “hot” surface 1606 of the TEG. The opposing second “cold” surface 1608 of the TEG is coupled to an inner surface of the housing 1604. In the design of FIG. 16, the TEG 1600 includes only a single large P-doped thermocouple element. The P-type element 1610 is coupled between a cold-side electrode 1612 and a hot-side electrode 1614. In use, heat from the hot side of the TEG 1600 warms the positive end of the P-type element 1610, relative to the opposing colder end, thus generating a ΔT and inducing a voltage between the opposing ends that causes current to flow in the direction of the arrows of the figure, i.e. current flows from hot-side electrode 1614 through the P-type element 1610 and into cold-side electrode 1612, with the resulting current fed through a power recharger 1618 of the drone. As with the asymmetric design of FIG. 15, since there is only a P-type element, less current will generally flow within a given area of the TEG than with a symmetric TEG as in FIG. 1. However, no alternating air gaps are needed. Also, it is noted that N-type materials often have better Seebeck coefficients than P-type materials and so the P-type design of FIG. 16 is expected to produce less voltage than the N-type design of FIG. 15. Still, a P-type symmetric TEG may have beneficial uses.

### Computer Modelling Results for Exemplary Drones

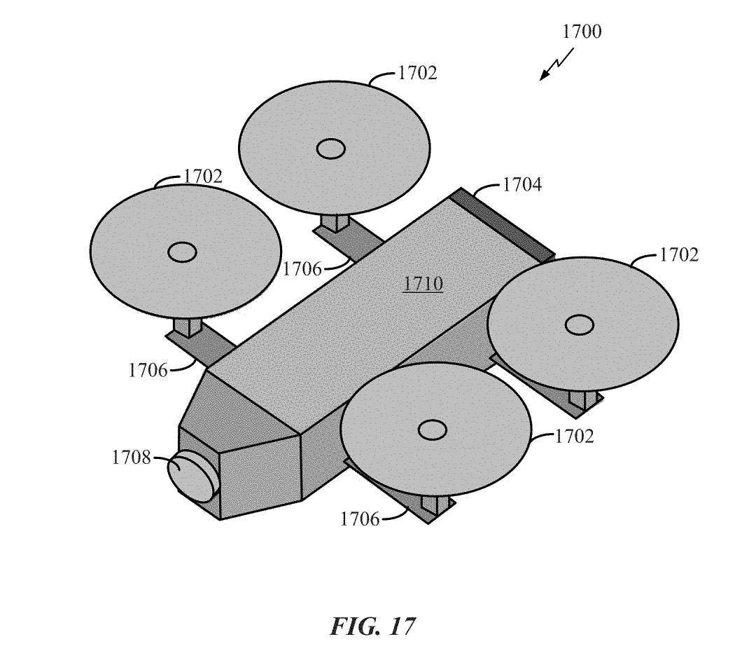

FIG. 17 provides a perspective view of a computer model 1700 of an aerial drone having a set of four rotors 1702 connected to a central drone enclosure 1704 via a set of struts 1706. The lens 1708 of a digital camera is shown projecting from a front portion of the drone enclosure 1704. A top or upper surface 1710 of the drone is a TEG. This is a simplified drone thermal model (obtained using the ANSYS IcePak® computation fluid dynamics package of ANSYS, Inc.) and was developed to evaluate the efficiency and effectiveness of energy harvesting for the drone using thermoelectric technology.

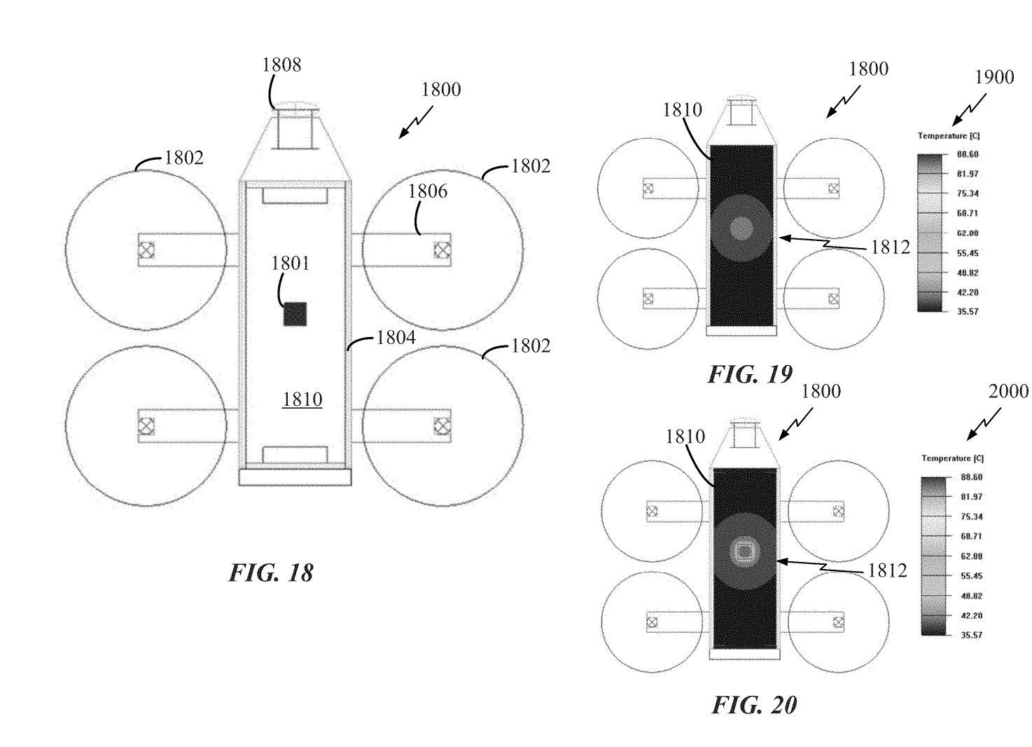

FIG. 18 provides a top view of a particular instance 1800 of the drone model 1700 of FIG. 17, wherein a 10 watt (W) processor chip 1801 is installed. (In the figure, selected internal components of the drone are shown, particularly the chip 1801.) The drone model again has a set of four rotors 1802 connected to a central drone enclosure 1804 via a set of struts 1806. The lens 1808 of a digital camera is shown projecting from a front portion of the drone enclosure 1804. A top or upper surface or sheet 1810 of the drone is the TEG. In this particular example, where the Total Power is 10 W, 8.0 W enters a bottom or lower surface of the TEG sheet 1810 for energy harvesting, 2.0 W enters a PCB board (not separately shown) on which the chip 1801 is mounted, positioned or coupled, and the thermal-to-electricity conversion efficiency is 4.64%. The Energy generated in this example by the TEG sheet 1810 is 464 mW.

FIG. 19 again provides a top view of the particular instance 1800 of the computer model where the 10 W chip is installed. In this illustration, the average temperature over the top (outer) metal surface of the TEG sheet 1810 is T_{cold}=40° C. Temperature graph 1900 provides gray-scale values for the modelled temperatures of the top surface of the TEG sheet 1810, showing the greatest amount of heat in the center 1812 of the top surface of the TEG sheet 1810, which is just above the chip 1801 (shown in FIG. 18).

FIG. 20 are provides another top view of the particular instance of the computer model where the 10 W chip is installed. In this illustration, the average temperature over the bottom (inner) metal surface of the TEG sheet 1810 is Tₕₒₜ=88° C. Temperature graph 2000 provides gray-scale values for the modelled temperatures of the inner surface of the TEG 1810, again showing the greatest amount of heat in the center 1812, which is just above the chip 1801 (shown in FIG. 18).

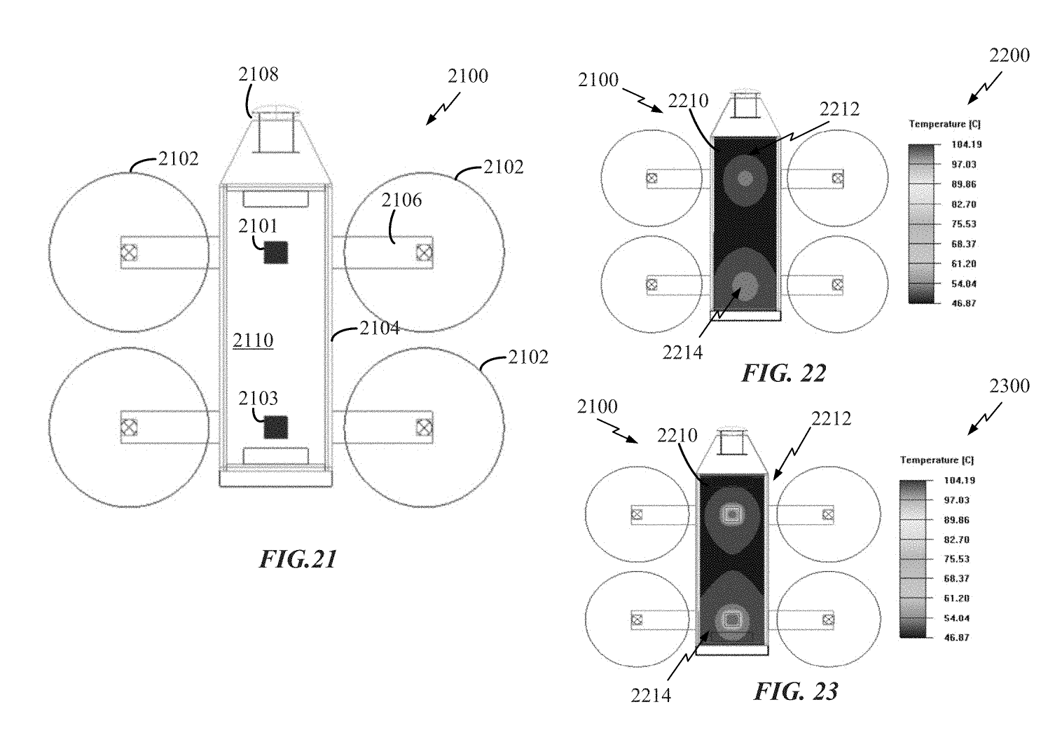

FIG. 21 provides a top view of a particular instance 2100 of the drone model 1700 of FIG. 17, wherein two 10 W processor chips 2101 and 2103 are installed. The drone model again has a set of four rotors 2102 connected to a central drone enclosure 2104 via a set of struts 2106. The lens 2108 of a digital camera projects from a front portion of the drone enclosure 2104. A top surface or sheet 2110 of the drone is the TEG. In this particular example, where the Total Power is 20 W, 15.8 W enters a bottom surface of the TEG sheet 2110 for energy harvesting, 4.2 W enters the PCB board (again not shown) on which the chips 2101 and 2103 are mounted, positioned or coupled, and the thermal-to-electricity conversion efficiency is 5.01%. The Energy generated in this example by the TEG sheet 2110 is 792 mW.

FIG. 22 are provides a top view of the particular instance 2100 of the computer model where the two 10 W chips are installed. In this illustration, the average temperature over the top (outer) metal surface of the TEG sheet 2110 is T_{cold}=50° C. Temperature graph 2200 provides gray-scale values for the modelled temperatures of the top surface of the TEG sheet 2110, showing the greatest amount of heat in the areas 2112 and 2214 that are just above the chips 2101 and 2103 (shown in FIG. 21).

FIG. 23 are provides another top view of the particular instance of the computer model 2100 of FIG. 21, wherein the two 10 W chips are installed. In this illustration, the average temperature over the bottom (inner) metal surface of the TEG sheet 2110 is Tₕₒₜ=104° C. Temperature graph 2300 provides gray-scale values for the modelled temperatures of the inner surface of the TEG 2110, again showing the greatest amount of heat in the areas 2112 and 2214 just above the chips 2101 and 2103 (FIG. 21).

One or more of the components, steps, features, and/or functions illustrated in FIGS. 1, 2, 3, 4, 5, 6, 7, 8, 9, 10, 11, 12, 13, 14, 15, 16, 17, 18, 19, 20, 21, 22 and/or 23 may be rearranged and/or combined into a single component, step, feature or function or embodied in several components, steps, or functions. Additional elements, components, steps, and/or functions may also be added without departing from aspects of the invention. One or more of the components, steps, features and/or functions illustrated in the figures may be rearranged and/or combined into a single component, step, feature or function or embodied in several components, steps, or functions. Additional elements, components, steps, and/or functions may also be added without departing from other features disclosed herein. The apparatus, devices, and/or components illustrated in the figures may be configured to perform one or more of the methods, features, or steps described in the figures. Any algorithms described herein may also be efficiently implemented in software and/or embedded in hardware.

In some examples, a non-transitory computer readable medium or machine readable may be provided that has instructions stored thereon for controlling a processor, such as the processor 1302 of FIG. 3. The instructions may serve to control the operation of the processor to control the aerial drone and its components. The machine-readable media may be part of the processing system separate from the processor. However, a machine-readable media, or any portion thereof, may be external to the processing system. By way of example, the machine-readable media may include a transmission line, a carrier wave modulated by data, and/or a computer product, all which may be accessed by the processor. Alternatively, or in addition, the machine-readable media, or any portion thereof, may be integrated into the processor.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. The term “die package” is used to refer to an integrated circuit wafer that has been encapsulated or packaged or encapsulated.

In addition, it is noted that the examples herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged, where appropriate. A process is terminated when its operations are completed. A process may correspond to a method, a function, a procedure, a subroutine, a subprogram, etc. When a process corresponds to a function, its termination corresponds to a return of the function to the calling function or the main function.

Those of skill in the art would further appreciate that the various illustrative logical blocks, modules, circuits, and algorithm steps described in connection with the examples disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system.

The various features described herein can be implemented in different systems. It should be noted that the foregoing aspects of the disclosure are merely examples and are not to be construed as limiting aspects of the invention. The present disclosure is intended to be illustrative, and not to limit the scope of the claims. As such, the present teachings can be readily applied to other types of apparatuses and many alternatives, modifications, and variations should be apparent to those skilled in the art.

What is claimed is:

1. An aerial drone, comprising:
a processor configured to control the aerial drone;
a power supply configured to power the processor; and
an energy harvesting device configured to convert heat generated by the processor into electricity for return to the power supply.

2. The aerial drone of claim 1, wherein the energy harvesting device is a solid state thermoelectric generator (TEG).

3. The aerial drone of claim 2, further including a heat-spreading component coupled to the TEG.

4. The aerial drone of claim 2, wherein a portion of the TEG is coupled to the processor.

5. The aerial drone of claim 2, wherein the aerial drone comprises a housing that contains the processor and wherein at least a portion of the TEG is coupled to the housing.

6. The aerial drone of claim 5, wherein the TEG forms at least a portion of the housing.

7. The aerial drone of claim 5, wherein at least a portion of the TEG is configured to protect internal components installed within the housing.

8. The aerial drone of claim 5, wherein at least a portion of the TEG is positioned in an airflow region outside of the housing.

9. The aerial drone of claim 5, wherein the aerial drone includes one or more rotors and wherein at least a portion of the TEG is positioned in an airflow region that receives airflow from the one or more rotors.

10. The aerial drone of claim 2, wherein the TEG comprises an asymmetric TEG formed of either only an N-type element or only a P-type element.

11. The aerial drone of claim 2, wherein the TEG comprises a symmetric TEG formed of alternating N-type elements and P-type elements.

12. The aerial drone of claim 1, further comprising an on-board electronic system including a video device, a camera device, a navigation device and/or a wireless communication device, and wherein the processor is configured to control the electronic system.

13. An apparatus for use with an aerial drone, comprising:
means for controlling the aerial drone;
means for providing power to the means for controlling; and
means for converting heat generated by the means for controlling into electricity for return to the means for providing power.

14. The apparatus of claim 13, wherein the means for converting heat includes means for converting heat into electricity using solid state components.

15. The apparatus of claim 14, further including means for spreading heat coupled to the means for converting heat.

16. The apparatus of claim 14, wherein a portion of the means for converting heat is coupled to the means for controlling.

17. The apparatus of claim 14, wherein the aerial drone includes a housing that contains the means for controlling and wherein at least a portion of the means for converting heat is coupled to the housing.

18. The apparatus of claim 17, wherein the means for converting heat forms at least a portion of the housing.

19. The apparatus of claim 17, wherein at least a portion of the means for controlling is configured to protect internal components installed within the housing.

20. The apparatus of claim 17, wherein at least a portion of the means for controlling is positioned in an airflow region outside the housing.

21. The apparatus of claim 17, wherein the aerial drone includes one or more rotors and wherein at least a portion of the means for converting heat is positioned in an airflow region that receives airflow from the one or more rotors.

22. The apparatus of claim 14, wherein the means for converting heat comprises an asymmetric thermoelectric generator (TEG) formed of either only an N-type element or only a P-type element.

23. The apparatus of claim 14, wherein the means for converting heat comprises a symmetric thermoelectric generator (TEG) formed of alternating N-type elements and P-type elements.

24. The apparatus of claim 13, further comprising an on-board electronic system including a video device, a camera device, a navigation device and/or a wireless communication device, and wherein the processor controls the electronic system.

25. A method for energy harvesting within an aerial drone having an energy harvesting device, a processor and a power supply, comprising:
operating the processor of the aerial drone using electricity provided by the power supply;
converting heat generated by the processor of the aerial drone into electricity using the energy harvesting device; and
returning the electricity obtained by the energy harvesting device to the power supply.

26. The method of claim 25, wherein converting heat generated by the processor of the aerial drone into electricity is performed using a solid state thermoelectric generator (TEG).

27. The method of claim 26, wherein converting heat generated by the processor of the aerial drone into electricity using the TEG includes:
applying heat from the processor to a first side of the TEG, the TEG also having a second side that is cooler than the first side;
coupling the first and second sides of the TEG to a circuit to obtain an electrical current; and
applying the electrical current to a recharger to obtain the electricity for returning to the power supply.

28. The method of claim 26, further including operating the aerial drone while using one or more rotors to provide lift and while using the TEG in an airflow region of the aerial drone that receives airflow from the one or more rotors.

29. The method of claim 26, wherein converting heat generated by the processor of the aerial drone into electricity is performed using an asymmetric TEG formed of either only an N-type element or only a P-type element.

30. A device for use with an aerial drone, comprising:
first and second electrodes;
a thermoelectric material composed of either only an N-type thermoelectric element or only a P-type thermoelectric element, with the thermoelectric material positioned between the first and second metal electrodes and with the thermoelectric material configured to generate a voltage in response to a temperature difference between the first and second metal electrodes;
a power supply; and
a circuit interconnecting the power supply and the first and second electrodes with the circuit configured to apply the voltage to the power supply to charge the power supply.
